(19) United States
(12) Patent Application Publication
(10) Pub. No.: US 2021/0359169 A1
(43) Pub. Date: Nov. 18, 2021

(54) Radiation Emitting Component and Method for Producing a Radiation Emitting Component

(71) Applicant: OSRAM Opto Semiconductors GmbH, Regensburg (DE)

(72) Inventor: Wim Hertog, Regensburg (DE)

(21) Appl. No.: 17/283,896

(22) PCT Filed: Oct. 7, 2019
(86) PCT No.: PCT/EP2019/077084

§ 371 Date: Apr. 8, 2021

(30) Foreign Application Priority Data
Oct. 11, 2018 (DE) 10 2018 125 138.6

(51) Int. Cl. H01L 33/50; H01L 33/32; H01L 33/46; H01L 33/60; H01L 25/075; H01L 33/00

(52) U.S. Cl. CPC H01L 33/504; H01L 33/325; H01L 33/46; H01L 2933/0041; H01L 25/0753; H01L 33/508; H01L 33/0095; H01L 33/60

(57) ABSTRACT

In an embodiment a radiation emitting component includes a radiation emitting semiconductor chip having a top surface and at least one side surface, wherein the radiation emitting semiconductor chip is configured to emit primary radiation, a carrier including a recess, a first conversion element and a second conversion element, wherein the first conversion element is arranged on the top surface of the radiation emitting semiconductor chip, wherein the second conversion element is arranged on the at least one side surface of the radiation emitting semiconductor chip, wherein the second conversion element does not project beyond a bottom surface of the first conversion element in a vertical direction, wherein the recess surrounds a first region on a top surface of the carrier, and wherein the radiation emitting semiconductor chip with the first conversion element and the second conversion element is arranged in the first region on the carrier.

This patent application is a national phase filing under section 371 of PCT/EP2019/077084, filed Oct. 7, 2019, which claims the priority of German patent application 102018125138.6, filed Oct. 11, 2018, each of which is incorporated herein by reference in its entirety.

### TECHNICAL FIELD

A radiation emitting component is specified. In addition, a method for producing a radiation emitting component is specified.

### SUMMARY

Embodiments provide a radiation emitting component that has a particularly good efficiency. Further embodiments provide a method for producing such a radiation emitting component.

A radiation emitting component is specified. The radiation emitting component is preferably a component that emits electromagnetic radiation, in particular visible light, during operation. For example, the radiation emitting component is a light emitting diode.

The radiation emitting component has a main extension plane. Here, a lateral direction is aligned parallel to the main extension plane and the vertical direction is aligned perpendicular to the main extension plane.

According to at least one embodiment, the radiation emitting component comprises a radiation emitting semiconductor chip, which has a top surface and at least one side surface. The top surface of the radiation emitting semiconductor chip preferably extends in lateral direction and is opposite to a bottom surface of the radiation emitting semiconductor chip. The top surface and the bottom surface of the radiation emitting semiconductor chip are connected by at least one side surface.

The radiation emitting semiconductor chip is preferably configured to generate primary electromagnetic radiation. The radiation emitting semiconductor chip can be a volume emitter. For example, a volume-emitting radiation emitting semiconductor chip has a substrate on which a semiconductor body is epitaxially grown or deposited. The substrate can comprise or consist of one of the following materials: sapphire, silicon carbide, gallium nitride, glass. Volume-emitting radiation emitting semiconductor chips generally emit the primary electromagnetic radiation not only through the top surface but also through the side surface. For example, in the volume-emitting radiation emitting semiconductor chip, at least 30% of the emitted primary radiation exits through the side surface.

The semiconductor body of the radiation emitting semiconductor chip is configured to generate the primary electromagnetic radiation. The semiconductor body preferably includes an active region, which can include a quantum well structure or a multiple quantum well structure. The active region is configured to generate the primary electromagnetic radiation.

The semiconductor body is, for example, an epitaxially grown semiconductor body. The semiconductor body can be based on or consist of a III-V compound semiconductor material. The III/V compound semiconductor material can be a nitride compound semiconductor material. Nitride compound semiconductor materials are compound semiconductor materials containing nitrogen, such as the materials from the system InₓAl_{y}Ga_{1-x-y}N with 0≤x≤1, 0≤y≤1 and x+y≤1. In particular, epitaxially grown semiconductor bodies with active regions based on a nitride compound semiconductor material are generally suitable for generating light from the ultraviolet to blue spectral range as primary electromagnetic radiation. In addition, semiconductor bodies based on a nitride compound semiconductor material can be epitaxially grown on a substrate comprising sapphire, silicon carbide, or gallium nitride. These materials are generally transparent to blue or ultraviolet primary radiation generated in the active region.

The radiation emitting semiconductor chip is, for example, a flip chip. The flip chip preferably has two chip contact areas on the bottom surface. Alternatively, it is possible that the top surface of the radiation emitting semiconductor chip is also electrically conductively contacted by means of at least one wire connection, for example, in the case of a volume-emitting semiconductor chip having a sapphire substrate.

Furthermore, it is possible that the radiation emitting component comprises at least two radiation emitting semiconductor chips, each of which can preferably be a volume emitter. In this case, the two radiation emitting semiconductor chips are preferably arranged spaced apart from one another, preferably in the lateral direction.

According to at least one embodiment, the radiation emitting component comprises a first conversion element. The first conversion element preferably comprises a first matrix material, in which first phosphor particles are incorporated. The first phosphor particles are preferably configured to convert primary electromagnetic radiation into first secondary electromagnetic radiation. For example, the primary radiation is ultraviolet to blue light. Further, the first secondary radiation is, for example, yellow to green light.

According to at least one embodiment, the radiation emitting component comprises a second conversion element. Preferably, the second conversion element comprises a second matrix material in which second phosphor particles are incorporated. The second phosphor particles are configured to convert primary electromagnetic radiation into second secondary electromagnetic radiation. For example, the second secondary radiation is red light.

The first matrix material and/or the second matrix material can be a resin, such as an epoxy or a silicone or a mixture thereof, or a ceramic material. The first matrix material and the second matrix material are preferably formed from the same material. Alternatively, the first matrix material and the second matrix material can be different from one another.

For the first phosphor particles and/or the second phosphor particles, each of the following materials can be suitable: Rare earth doped garnets, rare earth doped alkaline earth sulfides, rare earth doped thiogallates, rare earth doped aluminates, rare earth doped silicates, rare earth doped orthosilicates, rare earth doped chlorosilicates, rare earth doped alkaline earth silicon nitrides, rare earth doped oxynitrides, rare earth doped aluminum oxynitrides, rare earth doped silicon nitrides, rare earth doped sialons, quantum dots. These materials can also be used without the first matrix material and/or the second matrix material. The first conversion element and/or the second conversion element can then consist of any of the materials.

According to at least one embodiment, the first conversion element is arranged on the top surface of the semiconductor chip. Preferably, the first conversion element is in direct contact with the radiation emitting semiconductor chip. Furthermore, the first conversion element preferably does not project beyond the radiation emitting semiconductor chip in the lateral direction. Particularly preferably, the first conversion element completely covers the top surface of the radiation emitting semiconductor chip.

According to at least one embodiment, the second conversion element is arranged on the at least one side surface of the semiconductor chip. The top surface of the semiconductor chip is preferably free of the first conversion element. The second conversion element is preferably in direct contact with the side surface of the radiation emitting semiconductor chip. Furthermore, the second conversion element preferably does not project beyond the radiation emitting semiconductor chip in the vertical direction. Particularly preferably, the second conversion element completely covers the side surface of the radiation emitting semiconductor chip.

According to at least one embodiment, the second conversion element does not project beyond a bottom surface of the first conversion element in the vertical direction. The bottom surface of the second conversion element faces the radiation emitting semiconductor chip. Thus, the first conversion element preferably terminates flush with the top surface of the radiation emitting semiconductor chip in the vertical direction. The second conversion element thus preferably does not cover the first conversion element.

Due to the arrangement of the first conversion element on the top surface of the radiation emitting semiconductor chip and the arrangement of the second conversion element on the side surface of the radiation emitting semiconductor chip, the first conversion element and the second conversion element are preferably not in direct contact. However, due to manufacturing tolerances, it can be possible for the first conversion element to be in direct contact with the second conversion element in a comparatively small area where the top surface of the semiconductor chip and the at least one side surface of the semiconductor chip are in contact.

One idea of the radiation emitting component described herein is, among other things, to arrange the first conversion material only on the top surface and the second conversion material only on the side surface of the semiconductor chip. Such an arrangement advantageously prevents reabsorption of already converted primary radiation. By reducing the reabsorption of already converted primary radiation, absorption losses are reduced and an increased luminous flux or an increased light extraction of radiation from the radiation emitting component is achievable. In other words, the efficiency of the component is advantageously improved.

According to at least one embodiment, the first conversion element is configured to generate a first secondary radiation. Preferably, the first conversion element can convert electromagnetic primary radiation into electromagnetic first secondary radiation of a different wavelength range. For example, the first conversion element has first phosphor particles for this purpose, which converts electromagnetic primary radiation into electromagnetic first secondary radiation.

According to at least one embodiment, the second conversion element is configured to generate a second secondary radiation. Preferably, the first conversion element can convert electromagnetic primary radiation into electromagnetic second secondary radiation of a different wavelength range. For example, the second conversion element has second phosphor particles for this purpose, which converts electromagnetic primary radiation into electromagnetic second secondary radiation.

In particular, the first secondary radiation and the second secondary radiation can comprise longer wavelengths than the primary radiation. For example, the primary electromagnetic radiation is blue or ultraviolet light. For example, the electromagnetic first secondary radiation and the electromagnetic second secondary radiation can each be green, yellow, or red light.

According to at least one embodiment, the first secondary radiation comprises shorter wavelengths than the second secondary radiation. Preferably, the first secondary radiation is a yellow secondary radiation and/or a green secondary radiation. Particularly preferably, the first conversion element partially converts the blue primary radiation into yellow secondary radiation and/or green secondary radiation. A peak wavelength of the yellow secondary radiation is preferably between 570 nanometers and 600 nanometers, inclusive. A peak wavelength of the green secondary radiation is preferably between 490 nanometers and 570 nanometers, inclusive.

Further, the second secondary radiation is preferably a red secondary radiation. Particularly preferably, the second conversion element partially converts the blue primary radiation to red secondary radiation. A peak wavelength of the red secondary radiation is preferably between 600 nanometers and 780 nanometers, inclusive.

First phosphor particles that convert blue primary radiation to second green-yellow secondary radiation comprise, for example, a garnet phosphor obeying, for example, the chemical formula (Lu,Y)₃(Al,Ga)₅O₁₂:Ce³⁺. In particular, a LuAG phosphor obeying the chemical formula Lu₃Al₅O₁₂:Ce³⁺, a LuAGaG phosphor obeying the chemical formula Lu₃(Al,Ga)₅O₁₂:Ce³⁺, a YAG phosphor obeying the chemical formula Y₃AlO₁₂:Ce³⁺, or a YAGaG phosphor obeying the chemical formula Y₃(Al,Ga)₅O₁₂:Ce³⁺ are suitable for first phosphor particles that convert blue light into yellow-green light.

Second phosphor particles that convert blue primary radiation into second red secondary radiation have, for example, a nitride phosphor. The nitride phosphor can be, for example, an alkaline earth silicon nitride, an oxynitride, an aluminum oxynitride, a silicon nitride, or a sialon. For example, the nitride phosphor is (Ca,Sr,Ba)AlSiN₃:Eu²⁺, (Ca,Sr)AlSiN₃:Eu²⁺(SCASN), Sr(Ca,Sr)Al₂Si₂N₆:Eu²⁺ or M₂Si₅N₈:Eu²⁺ with M=Ca, Ba or Sr alone or in combination.

According to at least one embodiment, the radiation emitting component comprises a carrier. For example, the carrier comprises or consists of a plastic material, such as an epoxy or a silicone, or a ceramic material. Further, the carrier can comprise a metal. The carrier is or comprises, for example, a circuit board or a leadframe.

For example, the carrier is part of a housing comprising the carrier and at least one sidewall. The sidewall is preferably arranged on the carrier and forms a cavity in the housing. Further, the sidewall and the carrier can preferably be integrally formed with one another. The radiation emitting semiconductor chip or the at least two radiation emitting semiconductor chips are preferably arranged entirely within the cavity. That is to say that the radiation emitting semiconductor chip or the at least two radiation emitting semiconductor chips are arranged on a top surface of the carrier and the side wall of the housing projects beyond the semiconductor chip or the at least two semiconductor chips in the vertical direction.

According to at least one embodiment, the carrier comprises a recess. Preferably, the recess partially penetrates the carrier. That is to say that in the region of the recess, a material of the carrier is removed only up to a certain depth. A bottom surface of the recess is here preferably formed by non-removed areas of the carrier. Particularly preferably, the recess does not completely penetrate the carrier at any point.

According to at least one embodiment, the radiation emitting semiconductor chip is arranged on the carrier. The carrier further preferably comprises at least two contact areas, for example comprising a metal or consisting of a metal. The chip contact areas of the radiation emitting semiconductor chip can preferably be arranged on the at least two contact areas.

According to at least one embodiment, the carrier comprises a reflective coating on a top surface facing the radiation emitting semiconductor chip. Furthermore, the coating preferably has electrically conductive properties. Particularly preferably, the reflective coating comprises silver or is formed of silver. Preferably, the reflective coating is reflective for primary radiation emitted by the radiation emitting semiconductor chip, for example, light from the blue to ultraviolet spectral range. Further, the reflective coating can be reflective for the first secondary radiation and the second secondary radiation. Preferably, the reflective coating has a reflectivity of at least 90% for the primary electromagnetic radiation generated by the radiation emitting semiconductor chip. Further, the reflective coating preferably has a reflectivity of at least 90% for the first secondary radiation and the second secondary radiation.

Advantageously, the reflective coating is configured to direct the primary radiation and/or first secondary radiation and/or second secondary radiation emitted in the direction of the carrier to a light emitting surface of the radiation emitting component. Advantageously, an increased emission of light and efficiency of the radiation emitting component can thus be achieved.

According to at least one embodiment, the recess surrounds a first region at the top surface of the carrier. Preferably, the recess completely surrounds the first region in lateral direction. In other words, the recess surrounds the first region in a frame-like manner. The term “frame-like” is not to be understood as restrictive with respect to the shape and the course of the recess. For example, the recess can have a rectangular shape, a polygonal shape, a round shape, or an oval shape.

According to at least one embodiment, the radiation emitting semiconductor chip with the first conversion element and the second conversion element is arranged in the first region on the carrier. Preferably, the recess is formed such that the recess surrounds a mounting region for the radiation emitting semiconductor chip on the carrier. Particularly preferably, the first region forms the mounting region.

According to at least one embodiment, the recess is substantially free of a material of the second conversion element. “Substantially free” means that small amounts of the material of the second conversion element can be arranged in the recess due to the production process. In particular, the bottom surface of the recess is substantially free of the material of the second conversion element. Further, the material of the second conversion element can be present on the side surfaces of the recess limiting the recess, but the recess is not filled with the material of the second conversion element and thus is at least in places preferably completely free of the material of the second conversion element. In particular, preferably at most 1% of the volume of the recess is filled with material of the second conversion element.

According to at least one embodiment, a further first conversion element is arranged on a second region of a top surface of the carrier. The second region of the top surface of the carrier extends from the recess to the side wall of the housing. Preferably, the further first conversion element completely covers the top surface of the carrier in the second region. Preferably, the further first conversion element completely covers a side surface of the at least one side wall facing the semiconductor chip. In this case, the further first conversion element is preferably formed with the first matrix material and the first phosphor particles. Accordingly, the further first conversion element is also preferably formed to convert electromagnetic primary radiation into electromagnetic first secondary radiation.

Alternatively, the further first conversion element cannot project beyond the top surface of the radiation emitting semiconductor chip in vertical direction. In this case, the side surface of the at least one side wall facing the semiconductor chip is partially covered. The further first conversion element covers the side surface of the at least one side wall in this case up to a height that does not correspond to a maximum extension of the side surface in vertical direction.

According to at least one embodiment, the second region is arranged on the side of the recess facing away from the first region. Preferably, the second region completely surrounds the first region. Furthermore, the first region is preferably spaced apart from the second region by means of the recess. By being spaced apart, the further first conversion element is preferably not in direct contact with the second conversion element. Furthermore, the further first conversion element and the second conversion element preferably do not overlap in plan view.

According to at least one embodiment, the recess is substantially free of a material of the further first conversion element. Substantially free means that small amounts of the material of the further first conversion element can be arranged in the recess due to the production process. In particular, the bottom surface of the recess is substantially free of the material of the further first conversion element. Furthermore, the material of the further first conversion element can be present on the side surfaces of the recess limiting the recess, but the recess is not filled with the material of the further first conversion element and is thus at least in places preferably completely free of the material of the further first conversion element. In particular, preferably at most 1% of the volume of the recess is filled with material of the further first conversion element.

According to at least one embodiment, the first conversion element has a larger volume than the second conversion element. Preferably, the second conversion element is formed as a comparatively thin layer. For example, the thin layer has a thickness between 10 micrometers and 500 micrometers, inclusive. Preferably, the thickness of the thin layer is formed to be approximately constant so that the second conversion element is rectangular in cross-section, for example.

For example, if the component has the at least two radiation emitting semiconductor chips arranged spaced apart from one another, the second conversion element can be arranged between adjacent semiconductor chips. Atop surface of the second conversion element disposed therebetween can be formed flat, or have a concave or convex shape.

Alternatively, an outer surface of the second conversion element can be curved on a side opposite to the side surfaces of the semiconductor body. Further, an outer surface of the further first conversion element can be curved on a side facing the side surfaces of the semiconductor body. A cross-sectional area of the second conversion element and/or the further first conversion element thereby preferably increases toward an upper side of the component due to the curved shape. Here, the second conversion element and/or the further first conversion element is shaped convexly or concavely, for example. Alternatively, the second conversion element can be triangular in cross-section, for example.

According to at least one embodiment, the first conversion element does not overlap with the second conversion element in plan view. Further, it is possible that the first conversion element and the second conversion element do not overlap in plan view. Further, it is possible that the first conversion element and the second conversion element do not overlap in a side view. This arrangement allows the generated primary electromagnetic radiation to either exit through the top surface of the radiation emitting semiconductor chip and be converted to first secondary radiation by the first conversion element, or exit through the at least one side surface of the radiation emitting semiconductor chip and be converted to second secondary radiation by the second conversion element. A major part of the converted radiation, i.e. the first secondary radiation and the second secondary radiation, is then not guided through the respective other conversion element again. Advantageously, reabsorption of the converted light is thus reduced. Advantageously, the luminous flux emitted from the radiation emitting component is thus increased.

According to at least one embodiment, the radiation emitting semiconductor chip is a volume-emitting semiconductor chip. A radiant flux of the primary electromagnetic radiation emitted through the top surface of the radiation emitting semiconductor chip is increased compared to a radiant flux of the primary electromagnetic radiation emitted through the at least one side surface of the radiation emitting semiconductor chip. Advantageously, the second conversion element, which is generally comparatively more sensitive to heat, is arranged on the at least one side surface of the semiconductor chip. Since the radiant flux is reduced at the side surface of the semiconductor chip compared to the top surface of the radiation emitting component, the radiation emitting component advantageously heats up comparatively little and is thus more stable to aging.

According to at least one embodiment, the first conversion element is arranged only on the top surface of the semiconductor chip and the second conversion element is arranged only on the side surface of the semiconductor chip.

According to at least one embodiment, the primary radiation is blue light, the first secondary radiation is yellow to green light, and the second secondary radiation is red light. The respective conversion elements convert the primary radiation in each case only partially into the corresponding secondary radiation. Furthermore, in this embodiment, the primary radiation, the first secondary radiation and the second secondary radiation preferably mix to form white mixed light.

A method for producing a radiation emitting component is further specified. Preferably, the method is suitable for producing a radiation emitting component described herein. That is to say that a radiation emitting component described herein is producible by the described method or is produced by the described method. Any features disclosed in connection with the radiation emitting component are therefore also disclosed in connection with the method, and vice versa.

According to at least one embodiment, a semiconductor chip is provided in a step of the method. All features and embodiments disclosed in connection with the previously described radiation emitting semiconductor chip are also applicable in connection with the radiation emitting semiconductor chip described herein, and vice versa.

According to at least one embodiment of the method, a first conversion material is applied on the top surface of the semiconductor chip. In this case, the first conversion material has preferably a flowable form. In this case, the first conversion material is preferably cured after application to form the first conversion element. Further, the first conversion material can be applied by spraying, screen printing or doctoring.

According to at least one embodiment of the method, a second conversion material is applied to the at least one side surface of the semiconductor chip. The second conversion material has preferably a flowable form when applied. In this case, the second conversion material is preferably cured after application to form the second conversion element. Further, the second conversion material can be applied by spraying, screen printing or doctoring.

According to at least one embodiment of the method, the recess is generated in the carrier. Preferably, the recess can be generated by material removal of the carrier. The material removal of the carrier can be generated by a saw or a laser. Alternatively, it is possible to create the recess by punching or embossing.

According to at least one embodiment, the radiation emitting semiconductor chip is arranged on the carrier. The carrier preferably comprises a contact area which, for example, comprises or consists of a metal. Furthermore, the semiconductor chip preferably comprises at least one chip contact area, for example comprising or consisting of a metal. The at least one chip contact area can be adhered, bonded or soldered to the at least one contact area of the carrier. This connection attaches the semiconductor chip to the carrier.

According to at least one embodiment, a first edge of the recess acts as a first stopping edge for the second conversion material. Preferably, the first conversion material is first applied to the top surface of the semiconductor chip and cured to form the first conversion element. Preferably, the second conversion material is subsequently applied to the at least one side surface of the semiconductor chip. Preferably, the first stopping edge is the first edge formed by the top surface of the carrier and a side surface of the recess facing the radiation emitting semiconductor chip. In order for the first edge to perform the function of a stopping edge, the first stopping edge is preferably not rounded, but has a corner that is, for example, at a 90° angle or an angle <90′. That is to say the first stopping edge is preferably sharply defined, i.e., does not have any curves, nicks or notches. Since the second conversion material has preferably a flowable form during application, flowing away of the second conversion material out of the first region can thus advantageously be prevented.

According to at least one embodiment of the method, a further first conversion material is applied to the second region on the carrier. Preferably, the further first conversion material can be applied in the same manner as the first conversion material.

According to at least one embodiment of the method, a second edge of the recess acts as a second stopping edge for the further first conversion material. Preferably, the second stopping edge is the second edge formed by the top surface of the carrier and a side surface of the recess facing away from the radiation emitting semiconductor chip. In order for the second edge to perform the function of a stopping edge, the second edge preferably has the same characteristics as the first stopping edge described above. Since the further first conversion material has preferably a flowable form during application, flowing away of the further first conversion material out of the second region can advantageously be prevented. Furthermore, it is advantageously possible to prevent the further first conversion material from covering the second conversion material. In this way, the further first conversion material and the second conversion material are spaced apart from one another.

By the first stopping edge and/or the second stopping edge, it is further possible to adjust a course of an outer surface of the second conversion material and/or the further first conversion material from a concave shape to a convex shape including all intermediate levels. Without the first stopping edge and/or the second stopping edge, only the formation of the concave shape would be possible.

The course of the outer surface of the second conversion material and/or the further first conversion material can be adjusted, among other things, by changing a volume of the first conversion material and/or the further first conversion material. The outer surface of the second conversion material and/or the further first conversion material. By a choice of the volume of the second conversion material and/or the further first conversion material, for example, all intermediate levels from concave to convex shapes can be produced.

According to at least one embodiment of the method, the first conversion element and/or the second conversion element are produced by a sedimentation process and a subsequent curing process. The first phosphor particles are preferably sedimented in the first matrix material and/or the second phosphor particles are preferably sedimented in the second matrix material. In this case, the first matrix material and/or the second matrix material have preferably a flowable form. After the sedimentation process, the first conversion material and/or the second conversion material are cured to form the first conversion element and the second conversion element.

In a sedimentation process, the surface to be coated is provided in a volume that is filled with the matrix material containing the phosphor particles. Subsequently, the phosphor particles settle on the surface to be coated due to gravity. The settling of the phosphor particles can also be accelerated here by centrifuging. The use of a diluted matrix material also usually accelerates the sedimentation process.

A characteristic of a conversion element that has been applied by means of a sedimentation process is that all surfaces on which the phosphor particles can settle due to gravity are covered with the conversion element. Furthermore, the phosphor particles of a sedimented conversion element are usually in direct contact with one another.

### BRIEF DESCRIPTION OF THE DRAWINGS

In the following, the radiation emitting component described herein and the method for producing a radiation emitting component will be explained in more detail with reference to exemplary embodiments and the associated figures.

FIG. 1 shows a schematic representation of a radiation emitting component according to an exemplary embodiment;

FIG. 2 shows a schematic sectional view of the radiation emitting component according to the exemplary embodiment of FIG. 1;

FIGS. 3 and 4 show schematic sectional views of method stages of a method for producing a radiation emitting component according to an exemplary embodiment;

FIG. 5 shows exemplary an emission spectrum of a component according to an exemplary embodiment in comparison with an emission spectrum of a conventional component; and

FIG. 6 shows exemplary a comparison diagram.

Identical, similar or similar acting elements are provided with the same reference signs in the Figures. The Figures and the proportions of the elements shown in the Figures are not to be regarded as being to scale. Rather, individual elements can be shown exaggeratedly large for better representability and/or for better comprehensibility.

### DETAILED DESCRIPTION OF ILLUSTRATIVE EMBODIMENTS

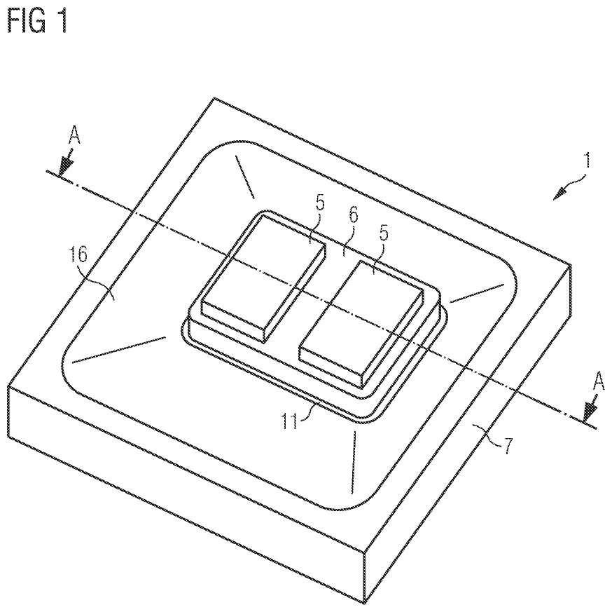

The radiation emitting component according to the exemplary embodiment of FIG. 1 comprises two radiation emitting semiconductor chips 1 covered by a first conversion element 5 and a second conversion element 6. The first conversion element 5 is respectively arranged on a top surface of the semiconductor chips 2, and the second conversion element 6 is respectively arranged on at least one side surface of the semiconductor chip 11. The second conversion element 6 does not project beyond a bottom surface of the first conversion element 5 formed by the top surface of the semiconductor chips 3 in vertical direction. Further, the second conversion element 6 is surrounded by a further first conversion element 16.

Furthermore, the component comprises a housing 7 having a carrier 8 and at least one side wall 10. The side wall 10 is arranged on the carrier 8 and forms a cavity 21 in the housing 7. The side wall 10 and the carrier 8 are integrally formed with one another. The dashed line shown between the side wall 10 and the carrier 8 is drawn here for better understanding and is accordingly of a virtual nature in the present case.

The carrier 8 has a recess 11 which completely surrounds the second conversion element 6. The recess 11 further separates the second conversion element 6 and the further first conversion element 16.

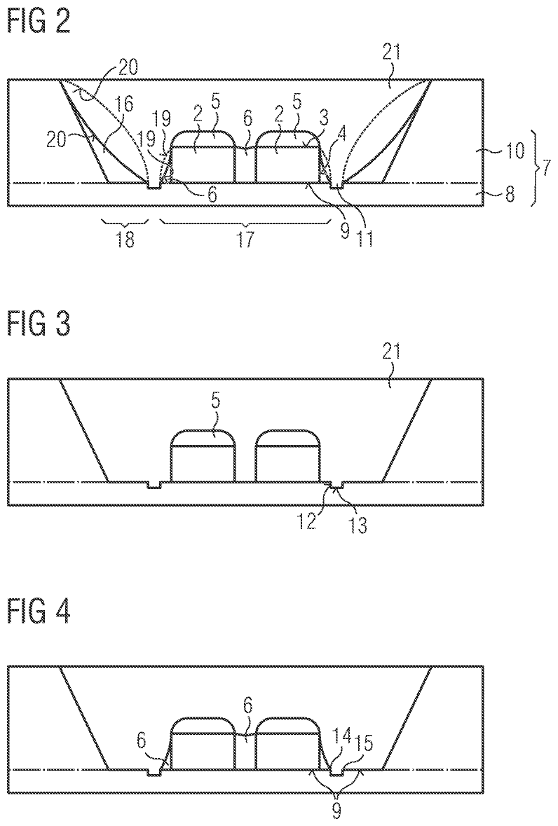

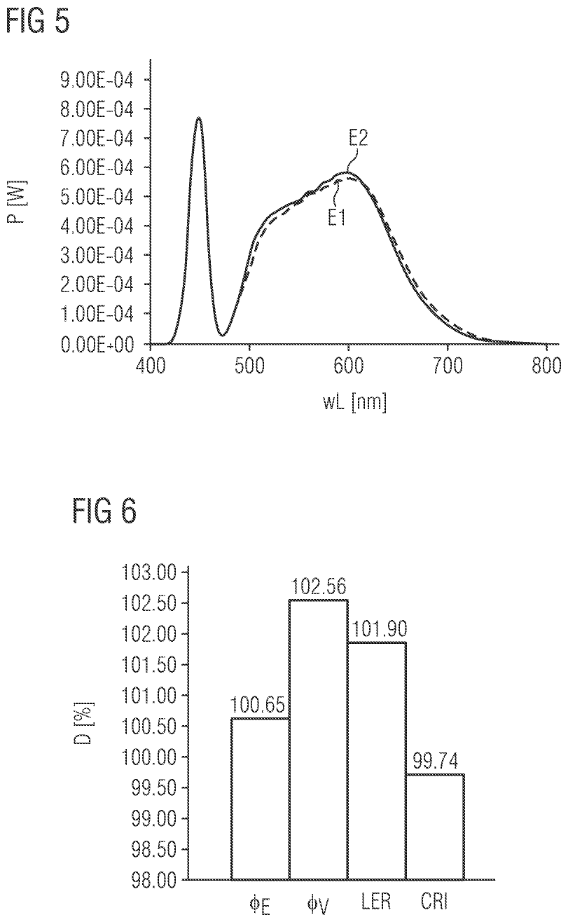

The schematic sectional view according to FIG. 2 shows a section along the line A-A of the component of FIG. 1. The semiconductor chips 2 are arranged in a first region 17 which is completely surrounded by the recess 11. The second region 18 is arranged on the side of the recess 11 facing away from the first region 17.

The second conversion element 6 is arranged between the semiconductor chips 2 being spaced apart from one another. The second conversion element 6 arranged between the semiconductor chips 2 completely covers side surfaces of the semiconductor chips 2 abutting thereon. A top surface of the second conversion element 6 arranged between the semiconductor chips 2 has a concave shape.

Furthermore, an outer surface of the second conversion element 19 extends in a curved shape on a surface facing away from the side surfaces of the semiconductor body 4. An outer surface of the further first conversion element 16 extends in a curved shape on a side facing the side surfaces of the semiconductor body 4. In this case, the shape of the second conversion element 6 is concave (solid outer surface 19) or convex (dashed outer surface 19).

The second conversion element 6 completely covers the top surface of the carrier 9 in the first region 17, which is not covered by the semiconductor chips 2, and the further first conversion element 16 completely covers the top surface of the carrier 9 in the second region 18. Furthermore, the further first conversion element 16 completely covers a side surface of the at least one side wall 10 facing the semiconductor chip 2. The recess 11 in the carrier is thereby free of a material of the second conversion element and a material of the further first conversion element.

In connection with the exemplary embodiment of FIGS. 3 and 4, method stages during a production of a radiation emitting component 1 are illustrated.

As shown in FIG. 3, a first conversion material is applied to the top surfaces of the provided semiconductor chips 2, respectively, and subsequently cured to form the first conversion element 5. The top surface of the semiconductor chip 2 is in each case completely covered by the first conversion element 5.

In a next method step, which is shown schematically in FIG. 4, a second conversion material is applied to at least one side surface of the semiconductor chip 11 and subsequently cured to form the second conversion element 6. Here, the second conversion material has a flowable form when applied. In this exemplary embodiment, a first edge of the recess 11 acts as a first stopping edge 14 for the second conversion material. The first stopping edge 11 is the first edge formed by the top surface of the carrier 9 and a side surface of the recess 11 facing the radiation emitting semiconductor chips 2. Advantageously, the first stopping edge 12 prevents the second conversion material from flowing away from the first region 17.

FIG. 5 schematically shows a simulation of an emission spectrum of a radiation emitting component according to an exemplary embodiment. The emission spectrum shows a relative radiation power P in watts W plotted over a wavelength wL in nanometers. A first emission spectrum E1 shows a typical emission spectrum of a conventional radiation emitting component, in which first phosphor particles of a first conversion element and second phosphor particles of a second conversion element are homogeneously mixed. A second emission spectrum E2 shows an emission spectrum of a radiation emitting component described herein. In the range between about 500 nanometers and about 620 nanometers, the relative radiation power P of the radiation emitting component described here is increased.

Furthermore, FIG. 5 shows exemplary simulation results, where a relative difference D is given as a percentage % of simulation parameters. The simulation parameters are a radiant flux (Φ_{E}), a luminous flux (Φ_{V}), a luminous efficiency (LER), and a color rendering index (CRI) of a radiation emitting component described herein in contrast to a conventional radiation emitting component in which a first conversion element and a second conversion element are arranged on a semiconductor chip and the second conversion element covers the first conversion element.

The invention is not limited to the exemplary embodiments by the description based thereon. Rather, the invention encompasses any new feature as well as any combination of features, which in particular includes any combination of features in the claims, even if this feature or combination itself is not explicitly stated in the claims or exemplary embodiments.

1.-17. (canceled)

18. A radiation emitting component comprising:
a radiation emitting semiconductor chip having a top surface and at least one side surface, wherein the radiation emitting semiconductor chip is configured to emit primary radiation;
a carrier comprising a recess;
a first conversion element; and
a second conversion element,
wherein the first conversion element is arranged on the top surface of the radiation emitting semiconductor chip,
wherein the second conversion element is arranged on the at least one side surface of the radiation emitting semiconductor chip,
wherein the second conversion element does not project beyond a bottom surface of the first conversion element in a vertical direction,
wherein the recess surrounds a first region on a top surface of the carrier, and
wherein the radiation emitting semiconductor chip with the first conversion element and the second conversion element is arranged in the first region on the carrier.

19. The radiation emitting component according to claim 18,
wherein the first conversion element is configured to generate a first secondary radiation,
wherein the second conversion element is configured to generate a second secondary radiation, and
wherein the first secondary radiation comprises shorter wavelengths than the second secondary radiation.

20. The radiation emitting component according to claim 18, wherein the carrier comprises a reflective coating on the top surface facing the radiation emitting semiconductor chip.

21. The radiation emitting component according to claim 18, wherein the recess is substantially free of a material of the second conversion element.

22. The radiation emitting component according to claim 18,
wherein a further first conversion element is arranged on a second region on the top surface of the carrier, and
wherein the second region is arranged on a side of the recess facing away from the first region.

23. The radiation emitting component according to claim 22, wherein the recess is substantially free of a material of the further first conversion element.

24. The radiation emitting component according to claim 18, wherein the first conversion element has a larger volume than the second conversion element.

25. The radiation emitting component according to claim 18, wherein the first conversion element does not overlap with the second conversion element in plan view.

26. The radiation emitting component according to claim 18, wherein the radiation emitting semiconductor chip is a volume emitting semiconductor chip.

27. The radiation emitting component according to claim 18,
wherein the first conversion element is arranged only on the top surface of the radiation emitting semiconductor chip, and
wherein the second conversion element is arranged only on the side surface of the radiation emitting semiconductor chip.

28. The radiation emitting component according to claim 27,
wherein the primary radiation is blue light,
wherein the first conversion element is configured to generate a first secondary radiation being yellow to green light,
wherein the second conversion element is configured to generate a second secondary radiation being red light, and
wherein the primary radiation, the first secondary radiation and the second secondary radiation mix to form white mixed light.

29. A method for producing the radiation emitting component according to claim 18, comprising:
providing the radiation emitting semiconductor chip;
applying a first conversion material to the top surface of the radiation emitting semiconductor chip; and
applying a second conversion material to the at least one side surface of the radiation emitting semiconductor chip.

30. The method according to claim 29, further comprising:
generating the recess in the carrier; and
arranging the radiation emitting semiconductor chip on the carrier,
wherein the recess surrounds the first region at the top surface of the carrier and
wherein a first edge of the recess acts as a first stopping edge for the second conversion material.

31. The method according to claim 30, further comprising applying a further first conversion material to a second region on the carrier, wherein a second edge of the recess acts as a second stopping edge for the further first conversion material.

32. The method according to claim 29, wherein the first conversion element and/or the second conversion element are generated by a sedimentation process and a subsequent curing process.
